(19) United States
(12) Patent Application Publication
(10) Pub. No.: US 2007/0216038 A1
(43) Pub. Date: Sep. 20, 2007

(54) Method for producing semiconductor components

(76) Inventors: Soo Gil Park, Radebeul (DE); Knut Kahlisch, Dresden (DE)

Correspondence Address: SLATER & MATSIL LLP, 17950 PRESTON ROAD, SUITE 1000, DALLAS, TX, 75252, US

(21) Appl. No.: 11/724,035

(22) Filed: Mar. 14, 2007

(30) Foreign Application Priority Data
Mar. 17, 2006 (DE) 10 2006 012 755.2

(51) Int. Cl. H01L 23/28; H01L 21/56

(52) U.S. Cl. 257/784; 438/127; 438/458; 438/464; 257/787

(57) ABSTRACT

A method produces semiconductor components having a substrate, a semiconductor chip and an encapsulant. Chips situated on a wafer are singulated, arranged on a substrate and electrically conductively connected to a conductor structure on the substrate. The chips on the substrate are encapsulated with an encapsulant and the semiconductor components are singulated by sawing up the encapsulant.

This application claims priority to German Patent Application 10 2006 012 755.2, which was filed Mar. 17, 2006, and is incorporated herein by reference.

### TECHNICAL FIELD

The invention relates to a method for producing semiconductor components having a substrate, a semiconductor chip and an encapsulant.

### BACKGROUND

As is known, in order to produce semiconductor components, semiconductor chips are produced on semiconductor wafers over a number of process steps.

For actual mounting, the chips are singulated. The singulated chips are then also referred to as dies. For this purpose, the wafer is applied to a carrier film, the so-called dicing tape, and subsequently sawn up along the chip edges. This operation is also referred to as “dicing”. A wafer is usually ground thin before or after dicing in order to be able to stack a plurality of chips one above another in the course of mounting without generating a large structural height.

The dies are then removed from the sawn-up wafer assemblage by being stripped away from the carrier film and mounted onto a substrate. In this case, the substrate itself provides a plurality of mounting locations for dies. By way of example, the dies can be mounted in a matrix of 4×4, with the result that 16 dies are arranged on a substrate. The dies are electrically conductively connected to a conductor structure on the substrate either in the course of mounting by means of flip-chip bonding or after adhesive bonding by means of wire bonding. The dies are subsequently enveloped with an encapsulant, a so-called mold compound. In this case, the dies are completely enveloped all together and encapsulated to form a block. Once this has been done, the block is subsequently sawn up between the individual dies arranged within the mold compound, whereby individual components then arise. The dies are then completely enclosed within the components.

The conductor structure of the substrate is expediently provided with solder balls on the underside of the substrate before the block is sawn up. The solder balls then subsequently serve for mounting a finished semiconductor component, for example, on a printed circuit board.

The arrangement of a die on a substrate is referred to as a package. In this case, it is also possible for a plurality of dies mounted one on top of another to belong to a package.

The arrangement of the dies at a distance from one another enables, on the one hand, the complete enveloping and also the lateral enveloping of the dies. On the other hand, the lateral extent of the semiconductor component is thereby increased. The waste area having no function whatsoever is pronounced, particularly in the case of very small chips. Mold compound is unnecessarily required for this, in particular, which causes the cost per component to rise. The component costs are also influenced by the fact that each individual die has to be handled separately. This lengthens the process times.

### SUMMARY OF THE INVENTION

In one aspect, the present invention provides the production of semiconductor components with increased productivity by shortening the process cycle time and achieving a saving of material by reducing the size of the components, in order thereby to obtain a reduction of costs overall.

For example, advantages can be obtained by the invention by virtue of the fact that at least two semiconductor chips joined in an unseparated manner are arranged on the substrate. The encapsulant is then deposited on the joined semiconductor chips. Finally, the semiconductor components are singulated by jointly sawing up the encapsulant and the semiconductor chips.

One advantage of the invention becomes clear by virtue of the fact that a sawing operation at the wafer level and a separate handling step can already be obviated for two joined chips. The separation of the joined chips and the separation of the encapsulant which holds together the two semiconductor components which each comprise one of the chips are effected in a single step.

In one preferred embodiment of the invention, a plurality of semiconductor chips, which are joined in an unseparated manner in a quadrangle, are arranged on the substrate. It is thereby possible for the wafer to be sawn up into individual quadrangles, each containing a plurality of semiconductor chips, by means of a few sawing cuts. A large number of sawing cuts, as would otherwise be required when sawing up the wafer in a chip-by-chip manner, can therefore be avoided. The removal of the individual chips from the wafer, too, is now no longer effected in a chip-by-chip manner, but rather for a plurality of chips by the removal of the respective quadrangle. A large number of handling steps can thus be saved.

The entire quadrangle is subsequently enveloped with encapsulant. It is only then that the quadrangle with the encapsulant arranged thereon is sawn up in a chip-by-chip manner. Thus, although the side edges of the chips are no longer enveloped with encapsulant, this is unimportant since an uncovering of the side areas does not have any disadvantageous effect. In principle, the non-active rear side of the chips could also be left free. However, the encapsulant arranged thereon has the crucial advantage that it yields additional mechanical stability to the semiconductor chips.

In one embodiment, the method can be developed by the complete wafer being arranged on the substrate. Even though, in the case of such an arrangement, particular requirements are made of the encapsulating with encapsulant and of the substrate, the advantages of the invention are nevertheless multiplied in the case of such a variant of the method. This is because when the wafer is arranged completely on the substrate, any sawing up of the wafer can be obviated. It is only with the singulation of the individual semiconductor components, that is to say with the sawing up of the encapsulant along the chip edges, that the wafer is also separated into individual chips. Moreover, individual handling steps for instance of individual chips or of quadrangles are saved in this way.

In a further embodiment of the method according to the invention, it is provided that the sides of a semiconductor chip which are not joined with another semiconductor chip are enveloped by the encapsulant, and that the encapsulant parts enveloping the sides of the semiconductor chip are sawn off along the sides of the semiconductor chip. This method step essentially concerns the semiconductor chips, for example, the edge chips of a quadrangle or chips of an edge of a wafer, which no longer have an adjacent semiconductor chip at a side. In order to attain a uniform design of the semiconductor components and identical conditions for all the semiconductor components, it is advantageous then also to eliminate the projecting parts of the encapsulant at the aforementioned chips.

### BRIEF DESCRIPTION OF THE DRAWINGS

The invention will be explained in more detail below on the basis of an exemplary embodiment. In the associated drawings:

FIG. 1 shows a schematic illustration of the sawing up of a semiconductor wafer according to the prior art;

FIG. 2 shows a chip-by-chip arrangement of semiconductor chips on a substrate in accordance with the prior art in plan view;

FIG. 3 shows a chip-by-chip arrangement of semiconductor chips on a substrate in accordance with the prior art in cross section;

FIG. 4 shows an enveloping of a chip-by-chip arrangement of semiconductor chips of the arrangement in accordance with FIG. 3 in cross section;

FIG. 5 shows a singulation of semiconductor components from an arrangement in accordance with FIG. 4 in cross section;

FIG. 6 shows a schematic illustration of the sawing up of a semiconductor wafer into quadrangles according to the invention;

FIG. 7 shows a quadrangle-by-quadrangle arrangement of semiconductor chips on the substrate according to the invention in plan view;

FIG. 8 shows a quadrangle-by-quadrangle arrangement of semiconductor chips on a substrate according to the invention in cross section;

FIG. 9 shows an enveloping of the arrangement in accordance with FIG. 3 in cross section; and

FIG. 10 shows a singulation of semiconductor components from an arrangement in accordance with FIG. 9 in cross section.

### DETAILED DESCRIPTION OF ILLUSTRATIVE EMBODIMENTS

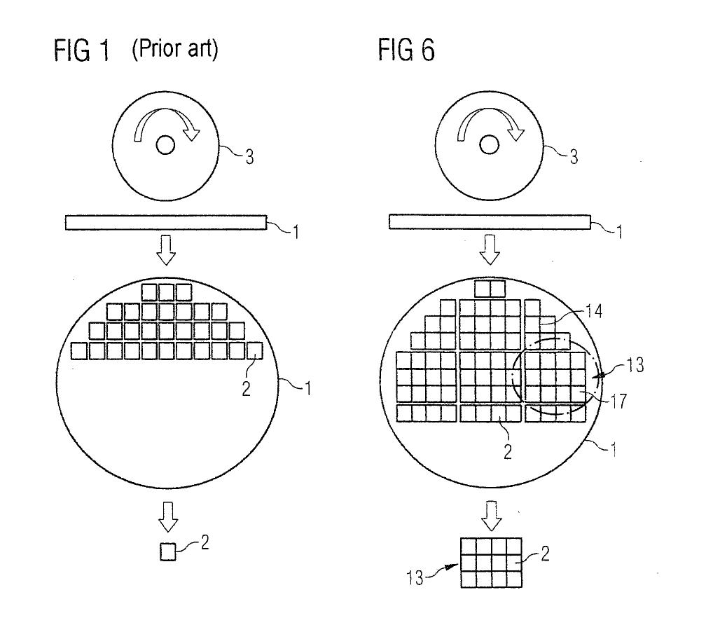

FIGS. 1 to 5 of the drawings illustrate the method according to the prior art. The individual method steps are depicted opposite FIGS. 6 to 10 for comparison here, for the sake of better illustrating the advantages of the invention.

As shown in FIG. 1, a multiplicity of semiconductor chips 2 are arranged on a wafer 1. For singulation, the wafer 1 is adhesively bonded onto a carrier film (not specifically illustrated). By means of a sawing operation, which is illustrated schematically by the saw blade 3 in FIG. 1, the chips 2 are singulated such that although the wafer 1 is severed, the carrier film remains undamaged.

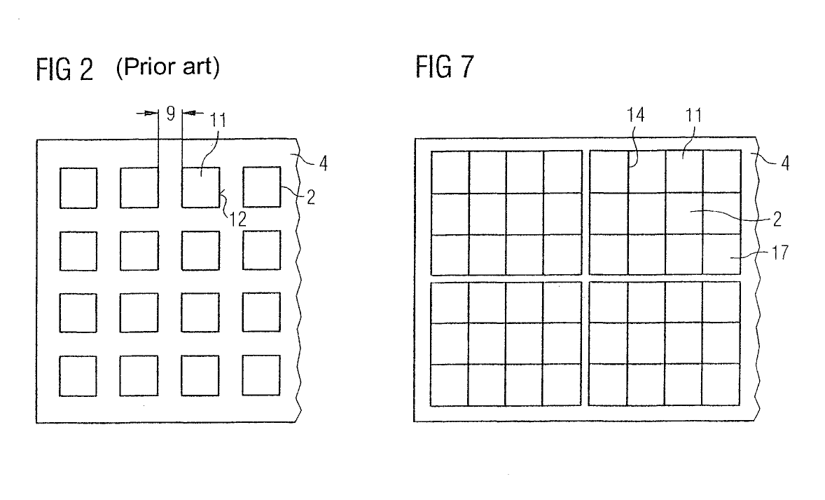

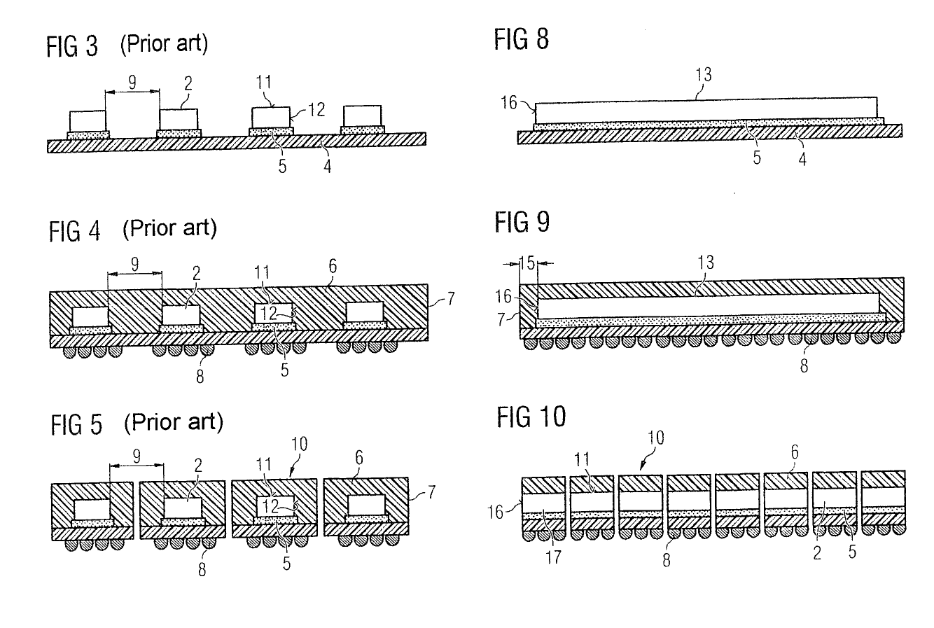

After the wafer 1 has been sawn up into individual semiconductor chips 2, the semiconductor chips 2 are taken from the carrier film and applied to a substrate 4, as is illustrated in FIG. 2 and FIG. 3. For this purpose, as shown in FIG. 3, an adhesive 5 is introduced between the semiconductor chips 2 and the substrate 4 and mechanically connects semiconductor chips 2 to the surface of the substrate 4.

Afterwards, a plurality of semiconductor chips 2 are encapsulated with an encapsulant 6, a so-called mold compound, in the form of a block 7, as is illustrated in FIG. 4. The substrate 4 is also provided with solder balls 8 for external contact-connection. The solder balls 8 are connected to a conductor structure on the substrate 4 in a manner that is not specifically illustrated, the conductor structure for its part having electrically conductive connections to contact islands on the semiconductor chips 2. The electrically conductive connections between the semiconductor chips 2 and the conductor structure on the substrate 4 may be produced by means of wire bonding connections, by way of example.

After the production of the blocks 7 in which the semiconductor chips 2 are arranged at a distance 9, the encapsulant 6 of the block 7 together with the substrate 4 is separated by means of sawing for instance at the centre of the distance 9. The semiconductor components 10 are thus produced. As can be seen in this respect in FIG. 5, the semiconductor chips 2 are completely enclosed in the encapsulant 6 on account of this process.

This complete enveloping is not absolutely necessary, however, since the rear sides 11 and the side areas 12 of each semiconductor chip 2 do not have any active components and therefore do not necessarily have to be protected. Consequently, the encapsulant 6 is not absolutely necessary on the right-hand side and left-hand side of the side areas 12. Consequently, these regions of the encapsulant 6 consume material and take up space.

As illustrated in FIG. 6, according to embodiments of the invention the wafer 1 is not sawn up into individual semiconductor chips 2, but rather into individual quadrangles 13. In this example, 3×4, i.e., 12, semiconductor chips 2 are combined in the quadrangle. As is evident in the comparison between FIG. 6 and FIG. 1, a considerable number of sawing cuts are avoided by virtue of this combination to form quadrangles 13.

The quadrangles 13 are then removed from the carrier film and adhesively bonded onto the substrate 4, as can be seen in FIG. 7 and FIG. 8. Afterwards, the quadrangles 13 adhesively bonded onto the substrate 4 are enveloped with encapsulant 6, whereby a block 7 once again arises.

The block, including the semiconductor chips 2 and the substrate 4, is sawn up along the chip boundaries 14, as can be seen in FIG. 6, whereby the semiconductor components 10 are produced. The edge regions 15 situated alongside the side areas 16 of the quadrangle 13 are likewise removed, with the result that the semiconductor components 10 produced from the semiconductor chips 17 at the edge have the same size as the rest of the semiconductor components 10 as shown in FIGS. 9 and 10.

As can be seen from FIG. 10 in comparison with FIG. 5, the semiconductor components 10 produced according to the invention have a significantly smaller structural size, which entails advantages in the case of use in practice and additionally leads to a space reduction. A lateral enveloping of the semiconductor chips 2 in the semiconductor components 10 produced according to the invention is not necessary. Consequently, the material of the encapsulant 6 at the side areas 16 of the semiconductor chip 2 can be obviated. The encapsulant 6 situated on the rear sides 11 of the semiconductor chips 2 serves on the one hand for protecting the rear side 11 against mechanical damage and additionally for mechanically stabilizing the semiconductor components 10 produced according to the invention. Moreover, an inscription for identifying the semiconductor component 10 can also be introduced on the encapsulant 6 in a favorable manner, which would be possible only poorly on the bare rear side 11 of the semiconductor chip 2.

1. A method for producing a semiconductor component, the method comprising:
providing a semiconductor wafer with a plurality of semiconductor chips disposed thereon;
arranging at least a portion of the semiconductor wafer over a substrate, the at least a portion of the semiconductor wafer comprising a plurality of semiconductor chips joined in an unseparated manner;
encapsulating the at least a portion of the semiconductor wafer over the substrate;
after encapsulating, separating the plurality attached semiconductor chips to form a plurality of semiconductor components.

2. The method of claim 1, further comprising separating the semiconductor wafer into a plurality of portions prior to encapsulating, wherein arranging at least a portion of the semiconductor wafer over a substrate comprises arranging one of the separated portions over the substrate.

3. The method of claim 1, wherein arranging at least a portion of the semiconductor wafer over a substrate comprises arranging an entire semiconductor wafer over the substrate.

4. The method of claim 1, wherein providing a semiconductor wafer comprises fabricating the plurality of semiconductor chips on the semiconductor wafer.

5. The method of claim 1, wherein the at least a portion of the semiconductor wafer comprises a quadrangle of semiconductor chips.

6. The method of claim 5, wherein the quadrangle of semiconductor chips comprises twelve semiconductor chips.

7. The method of claim 1, wherein arranging at least a portion of the semiconductor wafer over a substrate comprises adhesively bonding the at least a portion of the semiconductor wafer over the substrate.

8. The method of claim 1, wherein, after encapsulating, sides of a semiconductor chip that are not joined with another semiconductor chip are enveloped by the encapsulant, the method further comprising removing encapsulant parts enveloping the sides of the semiconductor chip.

9. The method of claim 8, wherein removing encapsulant comprises sawing the sides of the semiconductor chip.

10. The method of claim 1, further comprising arranging a plurality of solder balls at an underside of the substrate.

11. The method of claim 1, wherein encapsulating the at least a portion of the semiconductor wafer comprises forming an encapsulant over the at least a portion of the semiconductor wafer, the method further comprising forming an inscription for identifying the semiconductor component on the encapsulant.

12. A method for producing semiconductor components that comprise a substrate, a semiconductor chip and an encapsulant, wherein each chip is arranged on an associated substrate and electrically conductively connected to a conductor structure on the substrate, each chip on the substrate being encapsulated with the encapsulant, the method comprising;
arranging a plurality of attached semiconductor chips over a substrate;
forming encapsulant over the attached semiconductor chips; and
singulating the attached semiconductor chips by jointly sawing up the encapsulant and the semiconductor chips.

13. The method according to claim 12, wherein the plurality of attached semiconductor chips comprise a quadrangle of semiconductor chips.

14. The method according to claim 12, wherein mounting a plurality of attached semiconductor chips onto a substrate comprises arranging a complete wafer over the substrate.

15. The method according to claim 12, wherein forming encapsulant comprises forming encapsulant such that sides of a semiconductor chip that are not attached to another semiconductor chip are enveloped by the encapsulant, the method further comprising removing encapsulant parts enveloping the sides of the semiconductor chip.

16. A semiconductor component comprising:
a substrate having a top surface and a bottom surface joined by a plurality of side surfaces;
a semiconductor chip overlying the top surface of the substrate, the semiconductor chip having a plurality of side surfaces each of which is substantially co-planar with a corresponding one of the side surfaces of the substrate; and
a molding compound overlying the semiconductor chip, the molding compound having a plurality of side surfaces each of which is substantially co-planar with a corresponding one of the side surfaces of the semiconductor chip.

17. The semiconductor component of claim 16, further comprising an adhesive between the substrate and the semiconductor chip, the adhesive having a plurality of side surfaces each of which is substantially co-planar with a corresponding one of the side surfaces of the substrate.

18. The semiconductor component of claim 16, further comprising a plurality of solder balls disposed at the bottom surface of the substrate, ones of the solder balls being electrically coupled to the semiconductor chip.

19. The semiconductor component of claim 17, wherein the ones of the solder balls are electrically coupled to the semiconductor chip through wire bonds.

20. The semiconductor component of claim 16, further comprising an inscription for identifying the semiconductor component disposed on the molding compound.
